(19) United States
(12) Patent Application Publication
(10) Pub. No.: US 2014/0103508 A1
(43) Pub. Date: Apr. 17, 2014

(54) ENCAPSULATING PACKAGE FOR AN INTEGRATED CIRCUIT

(71) Applicant: TEXAS INSTRUMENTS INCORPORATED, Dallas, TX (US)

(72) Inventor: Juan A. Herbsommer, Allen, TX (US)

(73) Assignee: Texas Instruments Incorporated, Dallas, TX (US)

(21) Appl. No.: 13/649,896

(22) Filed: Oct. 11, 2012

(51) Int. Cl. H01L 23/495

(52) U.S. Cl. CPC H01L 23/495
USPC 257/676

(57) ABSTRACT

An apparatus is provided. An integrated circuit or IC is secured to a package housing. The IC has an IC substrate and an epitaxial layer formed over the substrate and having an active region and an upper surface. The upper surface is substantially exposed, and bond pads are formed over the epitaxial layer. Bond fixtures are each secured to and in electrical contact with at least one of the bond pads and with the package housing. A fill formed over at least a portion of the epitaxial layer so as to substantially encapsulate the active region, where the fill has a dielectric constant that is substantially equivalent to the dielectric constant of air. Additionally, the fill has a thickness, where the thickness is sufficiently large enough to confine parasitics of the active region at the upper surface of the epitaxial layer.

### TECHNICAL FIELD

The invention relates generally to an integrated circuit (IC) package and, more particularly, to a resonance matching IC package.

### BACKGROUND

Turning to FIGS. 1-3, an example of packaged IC 100 with an air gap package is shown. In this example, the IC 102 has an active region 306 formed with an epitaxial or epi layer 304 that is formed over an IC substrate 302. The active region 306 can include active elements and bond pads 308. For example, a laterally diffused MOS (LDMOS) transistor can be formed in epi layer 304 with bond pads 308 being coupled to the gate and drain of the LDMOS transistor. This IC 102 is then secured to a package housing. In this example, the package housing includes a source flange 104, a package substrate 106, a leadframe (which can generally comprise the drain flange 116 and gate flange 110 and which can be electrically isolated from the source flange 104 by way of package substrate 106), and lid 114. For example, the source flange 104 can be electrically coupled to the source of an LDMOS transistor formed in the active region 306 of the IC 102 by securing the IC to the source flange 104, while the drain flange 116 and gate flange 110 can be electrically coupled to the drain and gate of an LDMOS transistor formed in the active region 306 of the IC 102 by bond wires 108. Alternatively, the leadframe (e.g., the drain flange 116 and gate flange 110) can extend over the IC 102 and be secured to the IC 102 with solder bumps. The bond wires 108 or solder bumps can also be generally referred to bonding fixtures. The lid 114 can then be secured to the leadframe (e.g., the drain flange 116 and gate flange 110) with a bond 112 (e.g., epoxy) so as to allow an air cavity to be formed over IC 102.

The air gap package used with packaged IC 100 provides a mechanically stable package with very good performance characteristics, but there are some drawbacks. The biggest drawback being the cost. Therefore, there is a need for a lower cost package with comparable performance characteristics and mechanical stability.

### SUMMARY

In accordance with an embodiment of the present invention, an apparatus is provided. The apparatus comprises a package housing; an integrated circuit (IC) that is secured to the package housing, wherein the IC has: an IC substrate; an epitaxial layer formed over the substrate and having an active region and an upper surface, wherein the upper surface is substantially exposed; and a plurality of bond pads formed over the epitaxial layer; a plurality of bond fixtures, wherein each bond fixture is secured to and in electrical contact with at least one of the bond pads and with the package housing; and a fill formed over at least a portion of the epitaxial layer so as to substantially encapsulate the active region, wherein the fill has a dielectric constant that is substantially equivalent to the dielectric constant of air, and wherein the fill has a thickness, and wherein the thickness is sufficiently large enough to confine parasitics of the active region at the upper surface of the epitaxial layer.

In accordance with an embodiment of the present invention, the package housing further comprises a leadframe that is secured to and in electrical contact with the plurality of bond fixtures.

In accordance with an embodiment of the present invention, the leadframe extends over at least a portion of the IC, and wherein the plurality of bond fixtures further comprises a plurality of solder bumps.

In accordance with an embodiment of the present invention, the plurality of bond fixtures further comprises a plurality of bond wires.

In accordance with an embodiment of the present invention, the package housing further comprises: a flange that is secured to and in electrical contact with the IC; and a package substrate that is secured to the flange and the leadframe.

In accordance with an embodiment of the present invention, the flange further comprises a first flange, and wherein the leadframe further comprises: a second flange that is electrically coupled to at least one bond pad; and a third flange that is electrically coupled to at least one of the bond pads.

In accordance with an embodiment of the present invention, the active region further comprises a laterally diffused MOS (LDMOS) transistor that is coupled to the first flange at its source, the second flange at its drain, and the third flange at its gate.

In accordance with an embodiment of the present invention, a molding compound is applied to encapsulate the fill.

In accordance with an embodiment of the present invention, an apparatus is provided. The apparatus comprises a package housing having: a first flange; a package substrate secured to the first flange; a second flange secured to the package substrate; and a third flange secured to the package substrate; an IC having: an IC substrate that is secured to the first flange; an epitaxial layer formed over the substrate and having an LDMOS transistor in active region and an upper surface, wherein the upper surface is substantially exposed, and wherein the source of the LDMOS transistor is coupled to the first flange; and a first set of bond pads formed over the epitaxial layer, wherein the first set of bond pads are coupled to the drain of the LDMOS transistor; a second set of bond pads formed over the epitaxial layer, wherein the second set of bond pads are coupled to the drain of the LDMOS transistor; a first set of bond wires, wherein each bond wire from the first set of bond wires is secured to and in electrical contact with at least one of the bond pads from the first second of bond pad and with the second flange; a second set of bond wires, wherein each bond wire from the second set of bond wires is secured to and in electrical contact with at least one of the bond pads from the second of bond pads and with the third flange; and a fill formed over at least a portion of the epitaxial layer so as to substantially encapsulate the active region, wherein the fill has a dielectric constant that is substantially equivalent to the dielectric constant of air, and wherein the fill has a thickness, and wherein the thickness is sufficiently large enough to confine parasitics of the active region at the upper surface of the epitaxial layer.

In accordance with an embodiment of the present invention, the thickness is greater than 10 μm.

In accordance with an embodiment of the present invention, a molding compound is applied to encapsulate the fill.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of packaged IC that employs an air gap package;

FIG. 2 is a isometric view of the packaged IC of FIG. 1 with the lid removed;

FIG. 3 is a cross-sectional view of the IC of FIG. 1;

FIG. 4 is a cross-sectional view of a packaged IC employing a lower cost package; and

FIGS. 5-16 are charts illustrating performance characteristics of the packaged ICs of

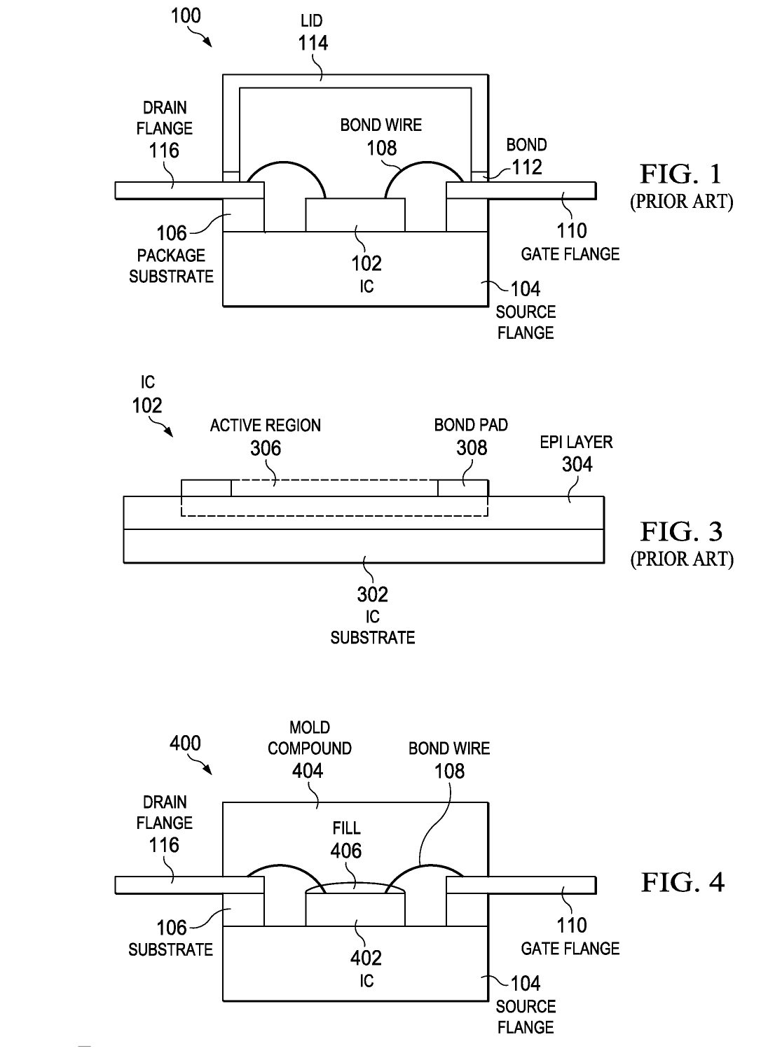

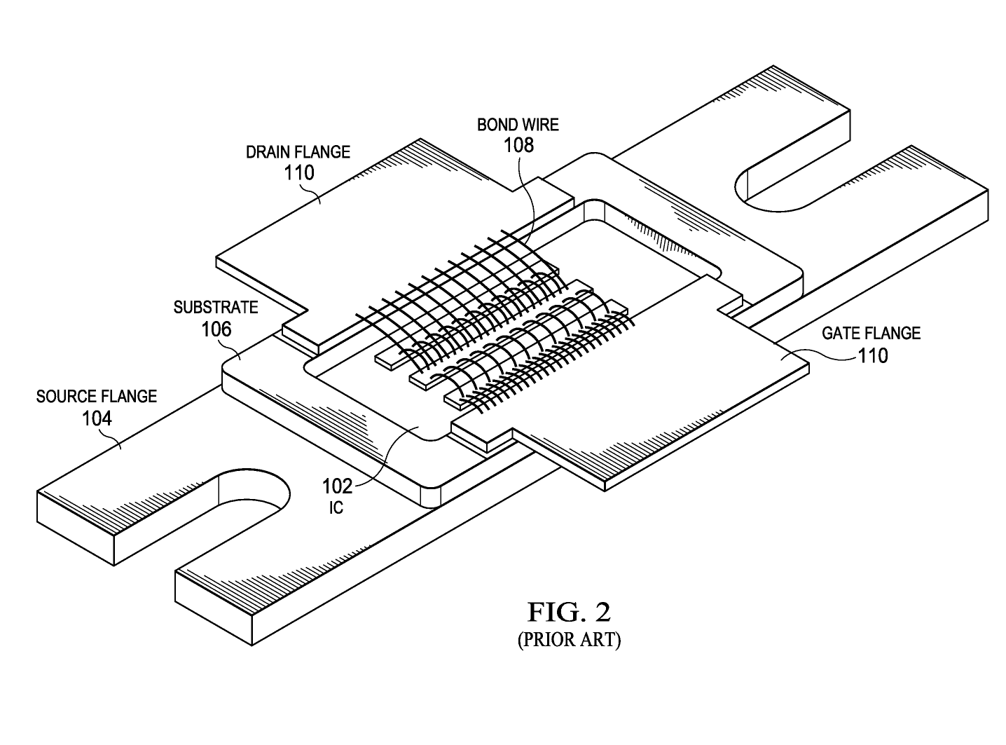

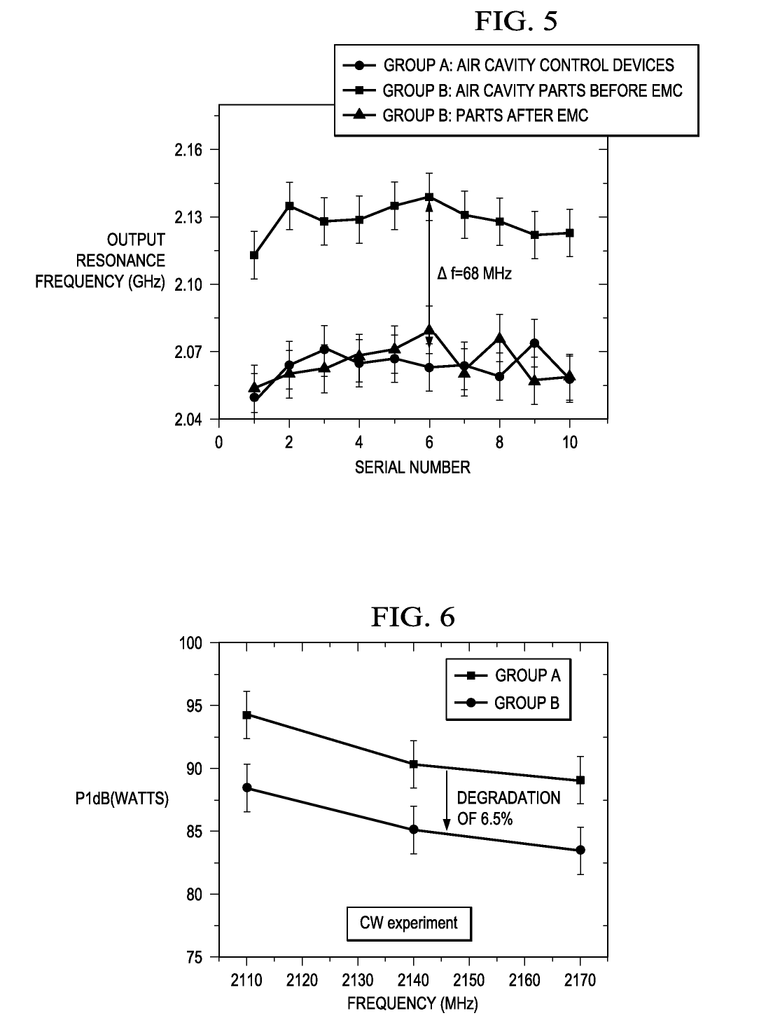

FIGS. 1 and 5.

### DETAILED DESCRIPTION

Refer now to the drawings wherein depicted elements are, for the sake of clarity, not necessarily shown to scale and wherein like or similar elements are designated by the same reference numeral through the several views.

When looking to migrate from an air gap package (e.g., packaged IC 100), conventional thought is generally insufficient. Some lower cost packages would be an epoxy mold compound (EMC) package and a green mold compound package, where, in each case, a mold compound is deposited directly onto the IC (e.g., IC 102), but conventional thought, though, would dismiss these types of packages as a replacement for air gap packages because empirical evidence shows significant performance degradation.

One reason for this is that most of literature related to EMC packages centers on the reliability, thermal, and mechanical performance. Almost no data can be found regarding the effects of mold compounds on the electrical performance of microelectronic devices. In other words, conventional thought ignored the impact of a mold compound on the electrical or electromagnetic performance. While this may appear to be intuitive, it is not, because most ICs do not include active components or an active region (e.g., active region 306) at the surface of an IC. This type of assembly is relatively uncommon, and techniques that are suitable for other conventional applications (e.g., microprocessors) may not be applicable for ICs that include active components or an active region (e.g., active region 306) at the surface.

For ICs that include active components or an active region (e.g., active region 306) at the surface, it can be said that when an active or passive device is encapsulated with a mold compound, the electromagnetic fields in the volume around the die and interconnects that carry the signals in and out the package are affected by the change of the dielectric constant (ε) and dissipation factor (tan δ) of the mold compound, namely for high frequency applications. Typical values of dielectric constant for mold compounds are around 4, and the dissipation factor is typically between about 0.001 and about 0.01. This means that, compared to air cavity packages (e.g., packaged IC 100), the electrical performance can be affected, mainly, in two aspects. The first aspect is related to the high dielectric constant of the mold compound that can increase the capacitive coupling between the structures in the surface of the die and also between the interconnects. The second aspect is related to an increment of losses due to the increase in the dissipation factor caused by the mold compound. This effect can cause degradation in the efficiency of the devices and generation of heat that should be dissipated in order to keep the temperature under specifications.

Turning to FIG. 1, an example of a packaged IC 200 with a lower cost package can be seen. In this example, IC 402 is similar to IC 102 in construction in that it includes an active region or active components at its surface and will typically include an epi layer formed over a substrate. For example, IC 402 can be an LDMOS high power high frequency transistor that can be used in the power amplifiers for the wireless infrastructure. This type of example device is able to deliver 90W of continuous RF power at frequencies of 2 GHz, and conventional packages are air cavity type (i.e., as shown in the example of FIG. 1). In this example and similar to packaged IC 100, there can be two dies (e.g., IC 402) coupled in parallel with wire bonds (e.g., 108) to the flanges (e.g., 110 and 116). The dies (e.g., IC 402) can have an area of about 5 mm² with a thickness of about 50 μm, and the package can be made of a copper-tungsten (CuW) alloy that can be designed to match the coefficient of thermal expansion of a Alumina cover (e.g., lid). The metal base (e.g., 104) can be plated with Au to be able to use an gold silicide (AuSi) eutectic die attach process.

The difference between packaged ICs 100 and 400 lies in the “cover.” With the example packaged IC 400, the lid 104 has been replaced with a fill 406 formed over the IC 402 and a mold compound 404 formed over the fill 406. Alternatively, the mold compound 404 can be omitted and a thicker fill 406 can be applied to the region illustrated as the mold compound 404. Typically, the fill 406 should encapsulate the upper or top surface of the IC 402 and be of sufficient thickness (e.g., greater than about 10 μm) to confine electromagnetic fields at the surface of the IC 402.

A reason for using fill 406 to confine electromagnetic fields at the surface of IC 402 relates to the change in the output resonant frequency of the parts imparted by the fill 406 itself Because IC 402 includes an active region at the surface, the parasitic capacitances and resistances and the inductance of the wires can form a resistor-inductor-capacitor (RLC) circuit. In order to maximize the transference of RF power to the load, the resonance frequency of the equivalent RLC circuit of the IC 402 (e.g., LDMOS transistor) should be matched to the specified frequency of operation of the amplifier. By filling the air cavity of the package with a mold compound 404, for example, the dielectric constant of the cavity increases from 1 (e.g., dry air) to approximately 4. The increase of the dielectric constant of the cavity affects the previously described RLC equivalent circuit in two ways. The first is due to an increase of the parasitic capacitances because the active devices (e.g., in the active region of IC 402) at the surface coupled through a media of a higher dielectric constant. For the second way, the fill 406 affects the resonant frequency due to the increased capacitive coupling between wire bonds.

In order to account for the effect of the fill 406 on the radio frequency (RF), samples were prepared (labeled Groups A and B in FIG. 5), with both groups having substantially the same output resonant frequency. Group A functioned as the control group, which employed an air cavity similar to that shown in FIG. 1. Group B included the wire bond length adjustments to obtain substantially the same resonant frequency as Group A (air cavity packages). The reduction in length of the wires reduces the inductance value of the RLC circuit and compensates for the increase of the parasitic capacitance explained above. The parasitic resistance, as shown in this example, is minimally affected and the final output resonant frequency of Group B, after application of fill 406, matches the output resonant frequency of Group A.

Once the output resonance of both Groups A and B have been substantially matched, a relatively accurate comparison of the performance can be accomplished by employing continuous wave RF measurements. In FIG. 6, the results of the measurement of the P1dB versus frequency for the center and edges of the Wideband Code Division Multiple Access (WCDMA) band. The one decibel compression point P1dB is generally defined as the power where the curve output RF power versus input RF power falls one decibel below the asymptotic linear characteristic. This parameter can be important in that it can define the maximum power a RF transistor can deliver at the linear regime. The effect of the fill 406 on P1dB is evident from the data that shows a clear deterioration of 6.5% in the maximum linear power the LDMOS transistor can deliver for the example shown in FIG. 6.

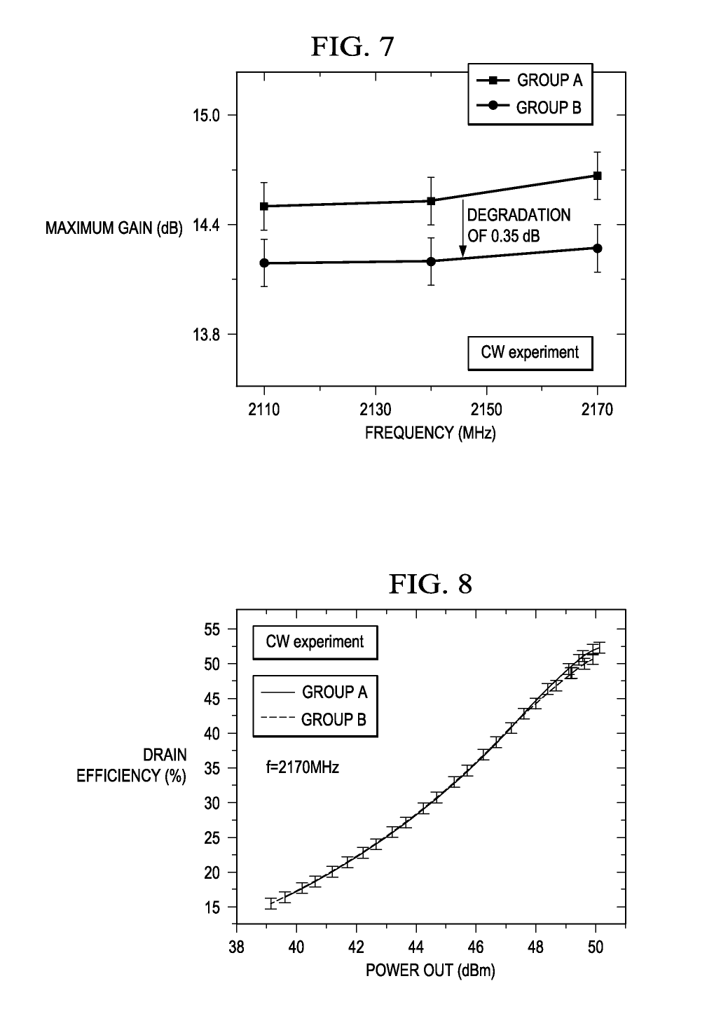

In FIG. 7, an example of a continuous wave measurement of maximum gain versus frequency for Groups A and B measured at the center and edges of WCDMA band can be seen. This parameter can be important as it measures the maximum gain the transistor can deliver in the linear regime. The curves show a worsening of 0.35 dB in maximum gain for the group that has a fill 406.

FIG. 8 shows an example of two typical curves of gain versus power out. This comparison shows that the fill 406 degrades the gain performance, not only at the peak of the curve (as shown in the example of FIG. 7), but in the entire range of output power. From the curves, it can be seen that there is a generally constant gain reduction of approximately 0.35 dB for the linear range. It can also be observed that the gain curve of the device with fill 406 falls in the nonlinear region at lower output power confirming that P1dB can be seriously affected.

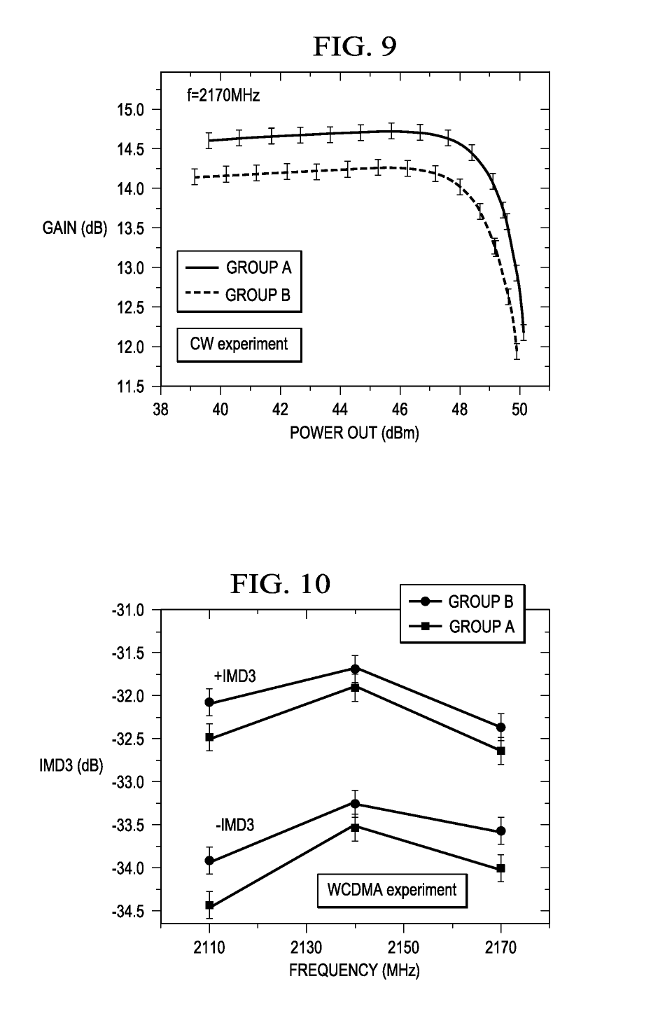

In FIG. 9, an example diagram of the drain efficiency versus RF output power can be seen. For output power up to 48 dBm in this example, it can be observed that there is no difference between the devices with fill 206 and the air cavity control parts. However, for output power above 48 dBm, there is a clear degradation of the drain efficiency. This degradation is likely due to loss tangent of material used for fill 406.

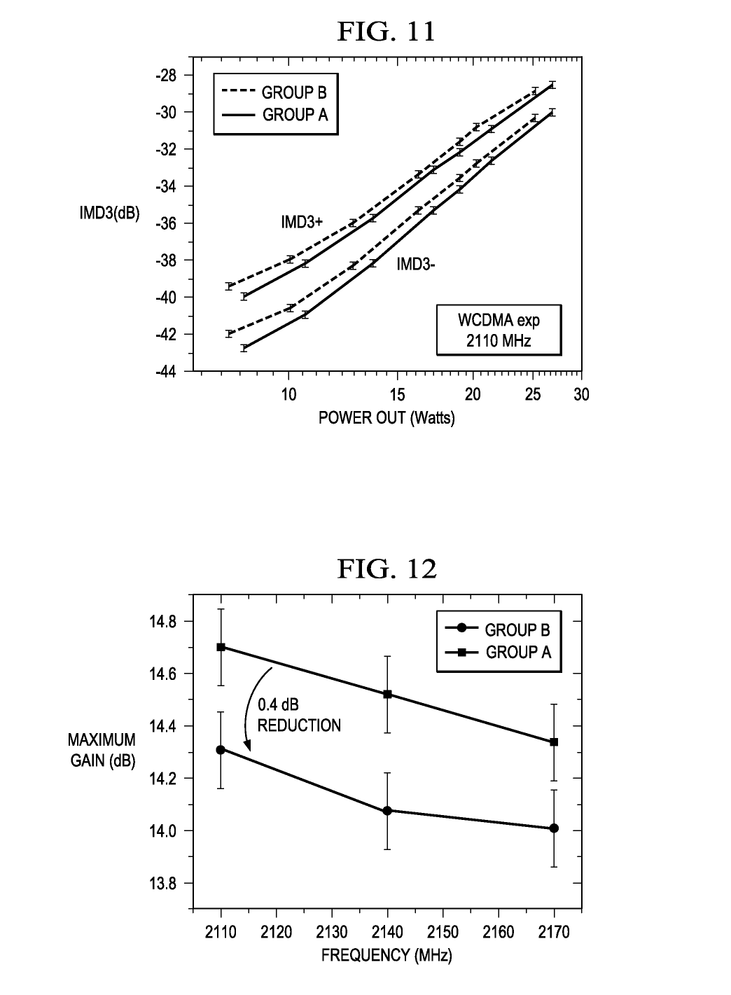

In order to understand the effects of fill 406 on the performance of the RF transistor while operating in a real application, a measurement employing both groups of transistors exciting them with a WCDMA modulation standard was made. FIG. 10 shows an example of the third order modulation distortion (IMD3) for control group A and group B as a function of frequency. IMD3 is generally defined as the ratio of the power in one of the third-order tones to that in one of the main tones. As one can observe, the fill 406 can increase the adjacent channel power degrading the linearity of the transistor. Additionally, FIG. 11 shows an example of two typical curves of IMD3 versus power out. In this plot, a degradation in the linearity of the devices due to the fill 406 can also be seen.

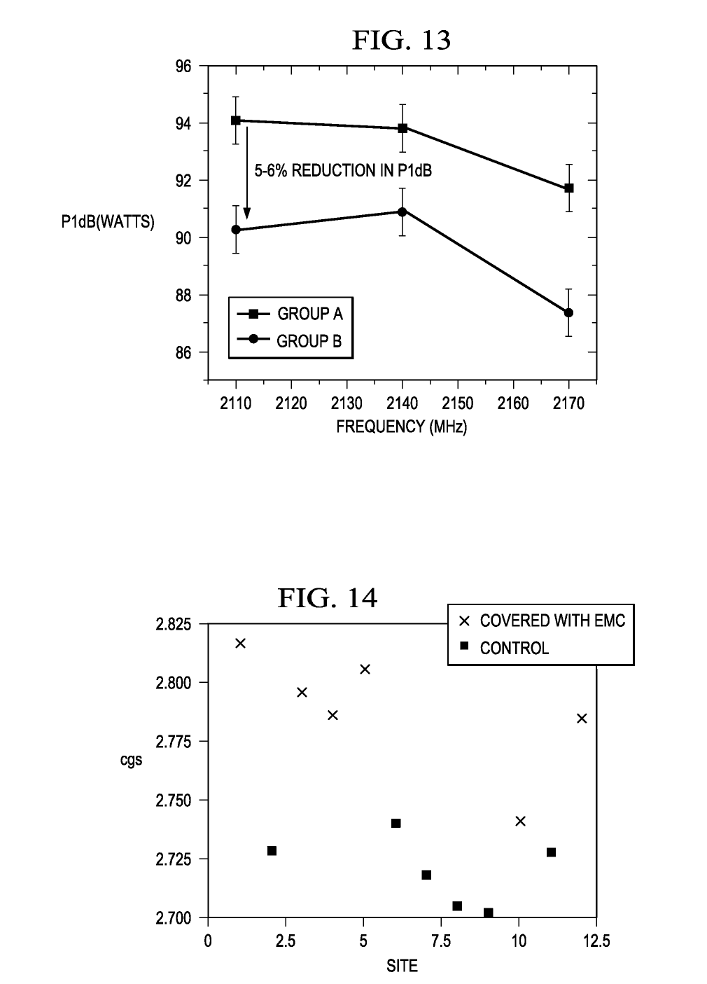

In the load pull measurements, the impedance seen can be varied by the output of the transistor to other than 50Ω in order to measure performance parameters. In the case of power transistors, a load pull power bench is used to evaluate large signal parameters such as compression characteristics, saturated power, efficiency and linearity as the output load is varied across the Smith chart. FIG. 12 shows an example of the load pull results obtained for P1dB as a function of frequency. It can be seen that there is a degradation of P1dB in the order of 5 to 6% when the fill 406 is employed. FIG. 13 shows an example of the results of the maximum gain as a function of frequency for Groups A and B measured using a load pull setup at the center and edges of the WCDMA band frequencies.

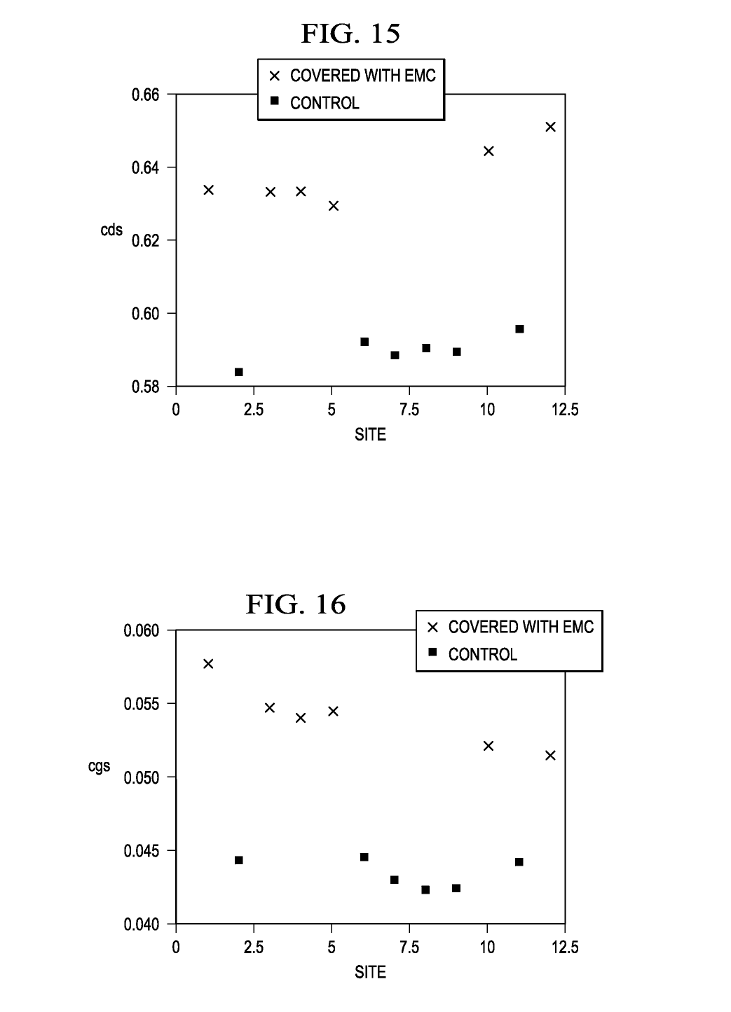

As it was explained above, when fill 406 is used, the change of the dielectric constant above the surface of IC 402 can change the capacitive coupling between different structures of the device (e.g., gate, drain, and source of an LDMOS transistor). FIGS. 14-16 show examples of the measurements of the parasitic capacitances. It can be seen that, on average, ICs having fill 406 can have a 4% higher values of gate-drain capacitance, a 10% higher drain-source capacitance, and a 20% higher gate-drain capacitance.

Therefore, in order to reduce the impact of the encapsulating material on the performance of the devices, it is necessary to use a low dielectric constant, low loss material to cover the die, probably using a glob-top technique. Preferably, the dielectric constant of the fill 406 should be approximately equal to that of dry air to achieve desirable results.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a package housing;
an integrated circuit (IC) that is secured to the package housing, wherein the IC has:
an IC substrate;
an epitaxial layer formed over the substrate and having an active region and an upper surface, wherein the upper surface is substantially exposed; and
a plurality of bond pads formed over the epitaxial layer;
a plurality of bond fixtures, wherein each bond fixture is secured to and in electrical contact with at least one of the bond pads and with the package housing; and
a fill formed over at least a portion of the epitaxial layer so as to substantially encapsulate the active region, wherein the fill has a dielectric constant that is substantially equivalent to the dielectric constant of air, and wherein the fill has a thickness, and wherein the thickness is sufficiently large enough to confine parasitics of the active region at the upper surface of the epitaxial layer.

2. The apparatus of claim 1, wherein the package housing further comprises a leadframe that is secured to and in electrical contact with the plurality of bond fixtures.

3. The apparatus of claim 2, wherein the leadframe extends over at least a portion of the IC, and wherein the plurality of bond fixtures further comprises a plurality of solder bumps.

4. The apparatus of claim 2, wherein the plurality of bond fixtures further comprises a plurality of bond wires.

5. The apparatus of claim 4, wherein the package housing further comprises:
a flange that is secured to and in electrical contact with the IC; and
a package substrate that is secured to the flange and the leadframe.

6. The apparatus of claim 5, wherein the flange further comprises a first flange, and wherein the leadframe further comprises:
a second flange that is electrically coupled to at least one bond pad; and
a third flange that is electrically coupled to at least one of the bond pads.

7. The apparatus of claim 8, wherein the active region further comprises an laterally diffused MOS (LDMOS) transistor that is coupled to the first flange at its source, the second flange at its drain, and the third flange at its gate.

8. The apparatus of claim 7, wherein a molding compound is applied to encapsulate the fill.

9. An apparatus comprising:
a package housing having:
a first flange;
a package substrate secured to the first flange;
a second flange secured to the package substrate; and
a third flange secured to the package substrate
an IC having:
an IC substrate that is secured to the first flange;
an epitaxial layer formed over the substrate and having an LDMOS transistor in active region and an upper surface, wherein the upper surface is substantially exposed, and wherein the source of the LDMOS transistor is coupled to the first flange; and
a first set of bond pads formed over the epitaxial layer, wherein the first set of bond pads are coupled to the drain of the LDMOS transistor;
a second set of bond pads formed over the epitaxial layer, wherein the second set of bond pads are coupled to the drain of the LDMOS transistor;
a first set of bond wires, wherein each bond wire from the first set of bond wires is secured to and in electrical contact with at least one of the bond pads from the first set of bond pad and with the second flange;
a second set of bond wires, wherein each bond wire from the second set of bond wires is secured to and in electrical contact with at least one of the bond pads from the second set of bond pad and with the third flange; and
a fill formed over at least a portion of the epitaxial layer so as to substantially encapsulate the active region, wherein the fill has a dielectric constant that is substantially equivalent to the dielectric constant of air, and wherein the fill has a thickness, and wherein the thickness is sufficiently large enough to confine parasitics of the active region at the upper surface of the epitaxial layer.

10. The apparatus of claim 9, wherein the thickness is greater than 10 μm.

11. The apparatus of claim 10, wherein a molding compound is applied to encapsulate the fill.
